(19) United States
(12) Patent Application Publication
(10) Pub. No.: US 2021/0124086 A1
(43) Pub. Date: Apr. 29, 2021

(54) Methods For Modeling Multiple Simultaneously Propagating Hydraulic Fractures

(71) Applicant: W.D. Von Gonten Laboratories, LLC, Houston, TX (US)

(72) Inventors: EGOR DONTSOV, Houston, TX (US); Roberto Suarez-Rivera, Houston, TX (US)

(21) Appl. No.: 17/067,061

(22) Filed: Oct. 9, 2020

Related U.S. Application Data
(60) Provisional application No. 62/913,849, filed on Oct. 11, 2019.

(51) Int. Cl. G01V 99/00; E21B 43/26; G06F 30/20

(52) U.S. Cl. CPC G01V 99/005; E21B 2200/20; G06F 30/20; E21B 43/26

(57) ABSTRACT

Methods for modeling hydraulic fractures using a geomechanical model of a formation and a completion design that includes a plurality of hydraulic fractures. A quantity of equivalent hydraulic fractures is selected to represent the plurality of hydraulic fractures. An equivalence ratio is determined using the quantity of equivalent hydraulic fractures and a fracture regime based on the geomechanical model and the completion design. The equivalence ratio is then used to update the geomechanical model and the completion design used as modeling inputs. The modeling results can then be modified using the equivalence ratio to compute a total surface area and fracture width of the plurality of hydraulic fractures.

### CROSS-REFERENCE TO RELATED APPLICATIONS

This application claims the benefit of U.S. patent application Ser. No. 62/913,849, filed Oct. 11, 2019 and incorporated herein by reference.

### BACKGROUND

Hydraulic fracturing is widely used to stimulate production from hydrocarbon wells, especially in unconventional reservoirs. Hydraulic fracturing often includes multiple perforations, or clusters of perforations, that are used to generate hydraulic fractures simultaneously, or near simultaneously, in order to increase the efficiency of reservoir stimulation. Further, the presence of natural fractures and other characteristics of the rock formation may also increase the number and nature of the fractures being formed. Modeling closely-spaced multiple fractures is time consuming and computationally costly as it requires complex meshing and the need to track evolution every fracture in the model.

Thus, there remains a need in the art to simplify the modeling of multiple closely-spaced fractures to determine the effectiveness and efficiency of hydraulic fracturing operations.

### BRIEF DESCRIPTION OF THE DRAWINGS

For a more detailed description of the embodiments of the disclosure, reference will now be made to the accompanying drawings, wherein:

FIG. 1 illustrates a method for simulating hydraulic fractures;

FIG. 2 is a schematic representation of an equivalent fracture representing multiple fractures and clusters in a single stage of a completion;

FIGS. 3A-3C are schematic representations of an equivalent fracture representing multiple fractures due to natural fractures.

### DETAILED DESCRIPTION

It is to be understood that the following disclosure describes several exemplary embodiments for implementing different features, structures, or functions of the invention. Exemplary embodiments of components, arrangements, and configurations are described below to simplify the disclosure; however, these exemplary embodiments are provided merely as examples and are not intended to limit the scope of the invention. Additionally, the disclosure may repeat reference numerals and/or letters in the various exemplary embodiments and across the Figures provided herein. This repetition is for the purpose of simplicity and clarity and does not in itself dictate a relationship between the various exemplary embodiments and/or configurations discussed in the various Figures. Finally, the exemplary embodiments presented below may be combined in any combination of ways, i.e., any element from one exemplary embodiment may be used in any other exemplary embodiment, without departing from the scope of the disclosure.

All numerical values in this disclosure may be exact or approximate values unless otherwise specifically stated. Accordingly, various embodiments of the disclosure may deviate from the numbers, values, and ranges disclosed herein without departing from the intended scope. Moreover, the formation of a first feature over or on a second feature in the description that follows may include embodiments in which the first and second features are formed in direct contact, and may also include embodiments in which additional features may be formed interposing the first and second features, such that the first and second features may not be in direct contact.

In the following discussion and in the claims, the terms “including” and “comprising” are used in an open-ended fashion, and thus should be interpreted to mean “including, but not limited to.” Furthermore, as it is used in the claims or specification, the term “or” is intended to encompass both exclusive and inclusive cases, i.e., “A or B” is intended to be synonymous with “at least one of A and B,” unless otherwise expressly specified herein.

Certain terms are throughout the following description and claims refer to particular components. As one having ordinary skill in the art will appreciate, various entities may refer to the same component by different names, and as such, the naming convention for the elements described herein is not intended to limit the scope of the invention, unless otherwise specifically defined herein. Further, the naming convention used herein is not intended to distinguish between components that differ in name but not function.

Disclosed herein are methods that significantly reduce the computational costs required for simulating multiple hydraulic fractures that are generated simultaneously (e.g., multiple fractures per cluster, multiple fractures per stage, multiple fractures associated to fracture branching at the intersection between natural fractures and the hydraulic fracture). Thus, the disclosed methods can be utilized to perform a large number of simulations, in a short time, to understand sensitivity and optimize result with respect to problem parameters, which is not feasible or practical using the existing methods. These methods also allow for the implicit inclusion of the effect of natural fractures, their spatial distribution, and the effect of natural fractures on the model results.

The disclosed methods are based on the realization that, at some distance away from multiple fractures, the effect of the multiple fractures in relation to their perturbation of the in-situ stress (i.e., stress shadow) cannot be differentiated from that of an equivalent system with a small number of equivalent (e.g., wider) fractures. Thus it is possible to represent the simultaneous propagation of multiple fractures with a reduced number of equivalent fractures, which accurately describes the overall fracture geometry, the created surface area, propped surface area, fluid leakoff, and the resulting induced stresses as resulting from the original configuration.

Because this approach considerably reduces the number of fractures required to model, the computational time and cost is reduced considerably, without altering the final results and conclusions. The methodology of representing multiple hydraulic fractures with a reduced number of equivalent fractures allows for the effective consideration of fracture complexities observed in the field in hydraulic fracture and/or reservoir modeling, including multiple fractures per cluster and fracture branching associated to the presence of fractures and faults within specific formations.

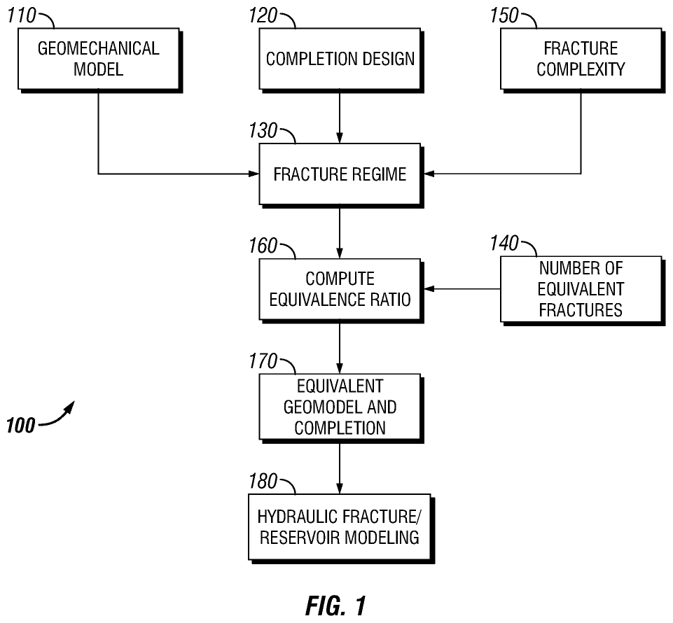

Referring now to FIG. 1, a method for modeling hydraulic fractures 100 includes selecting a geomechanical model (geomodel) 110 of the formation to be analyzed. This could be a single well 2D model (i.e., homogeneous layer cake model) or a multi-well 3D model (i.e., heterogeneous model). The geomodel should include input properties needed for hydraulic fracture and reservoir modeling including, but not limited to, reservoir pressure, in-situ stress, rock anisotropic elastic properties, fracture toughness, leak-off coefficient, permeability, hydrocarbon-filled porosity, and others, varying as a function of depth and areal extent.

Method 100 also includes selecting a completion design 120 to be analyzed. Selecting the completion design 130 includes specifying the well location and the details of the completion design including, but not limited to the number and placement of stages, and the number and configuration of perforation clusters and pumping rates. The completion design may also include the proppant and fracturing fluid types, properties, and concentrations.

Once selections of a geomodel 110 and completion design 120 are made, the dominant fracture regime is selected 130. The fracture regime is selected based on the properties of the rock as defined in the geomodel and details of the completion design based on what a person of skill in the art would recognize as the dominant energy loss during propagation of the hydraulic fractures. There are four fracture regimes, namely storage-viscosity, storage-toughness, leak-off-viscosity, and leak-off-toughness. The storage-viscosity fracture regime corresponds to almost no leak-off and domination of viscosity over fracture toughness. The storage-toughness fracture regime corresponds to almost no leak-off and domination of toughness over viscosity. The leak-off-viscosity fracture regime corresponds to very small efficiencies (i.e. high leak-off) and domination of viscosity over fracture toughness. The leak-off-toughness fracture regime corresponds to very small efficiencies and domination of toughness over viscosity.

In additional to selecting the fracture regime 130, the method also includes selecting the number of equivalent fractures 140 that will be used to represent the actual number of fractures to be created. The number of equivalent fractures can be anywhere from one to the total number of fractures in the completion design. The number of equivalent fractures may be minimized if the desire is to achieve a maximum reduction in analysis time or maximized to reduce uncertainty in the result of the analysis.

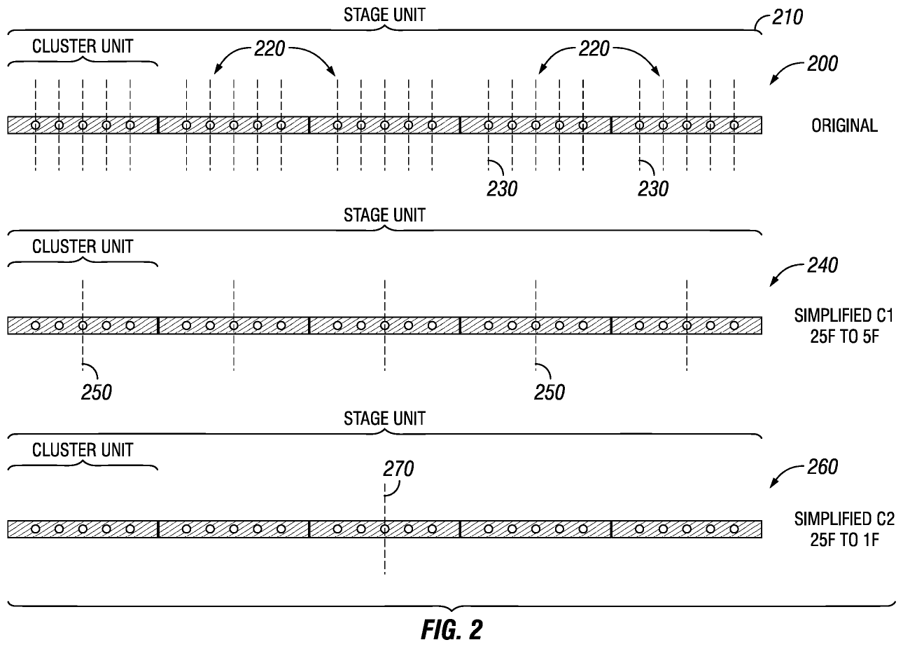

Referring now to FIG. 2, a completion design 200 may include one stage 210 having five fracture clusters 220 where each fracture cluster 220 includes five fractures 230. Therefore, a full simulation of this design would require modeling twenty five fractures. A simplified completion design 240 may include a single equivalent fracture 250 representing the all the fractures 230 in each of the fracture clusters 220. A further simplified completion 260 may include a single equivalent fracture 270 for all of the fractures 230 in the entire stage 210.

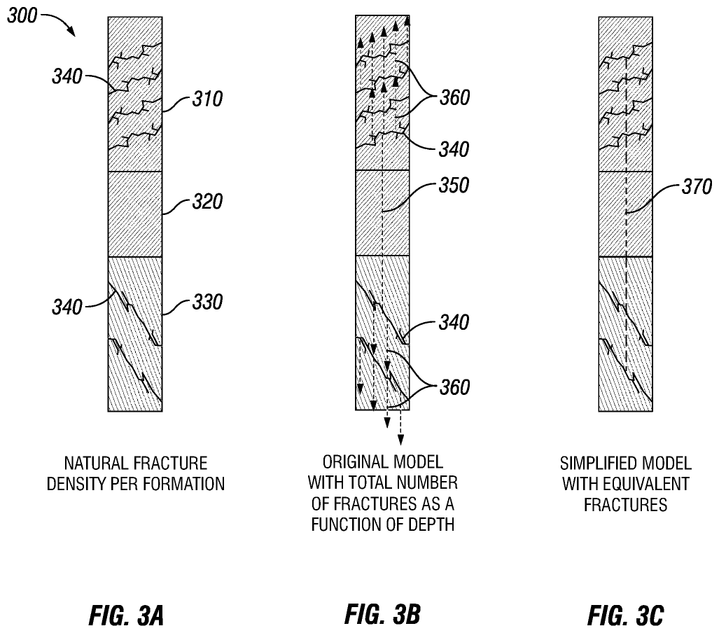

Referring now to FIGS. 3A-C, a formation 300 includes an upper section 310, middle section 320, and lower section 330. The upper section 310 and lower section 330 have natural fractures 340 of varying density, orientation, and properties. The middle section 320 has no natural fractures. As a hydraulic fracture 350 is formed and propagates vertically, it encounters the natural fractures 340 and branches out into multiple branched fractures 360. The number of multiple fractures 360 will depend on the density, orientation, and properties of the natural fractures 340.

Referring back to FIG. 1, in certain embodiments, method 100 may also include specifying a natural fracture complexity factor 150 to take into account the branching of the fracture. In reference to FIGS. 3B-C, the natural fracture complexity factor allows for the hydraulic fracture 350 and branched fractures 360 to be analyzed as a single fracture 370. The natural fracture complexity factor defines the degree of fracture complexity (e.g., fracture branching) resulting from the interaction between natural fractures and hydraulic fractures, on a depth segment basis (e.g., by formation, reservoir unit, or unit depth segment). The natural fracture complexity factor may be drawn from a database or a model that designates a factor based on the natural fracture density, orientation, and properties per depth.

Selection of an equivalence ratio 160, defined as the ratio between the surface area of all the original fractures to the surface area of all equivalent fractures, can be done once the fracture regime, number of equivalent fractures, and natural fracture complexity factor (if desired) have been selected. The equivalence ratio may be selected from a database that relates different fracture regimes, number of equivalent fractures, and natural fractures to corresponding equivalence ratio values. The equivalence ratio may vary as a function of depth when considering natural fractures.

The database of equivalence ratios may be constructed using a 3D fully coupled numerical simulator to run a large number of simulations with the same number of fractures and different fracture regimes and the same fracture regimes and different number of equivalent fractures. Selection of the equivalence ratio from the database can be implemented as a search function to the tabulated values in the database, or alternatively, and functional relationship can be obtained by curve fitting and subsequently use this to calculate the appropriate value.

Certain properties of the geomodel and completion design are updated 170 using the selected equivalence ratio. In particular, the parameters that serve as inputs for modeling hydraulic fractures, including, but not necessarily limited to, fracture toughness, fluid viscosity, proppant diameter, fluid leak off and others, are modified by the corresponding equivalence ratios, such that the results of the simplified equivalent model, with reduced number of fractures, provides identical or similar results to the original model.

In certain embodiments the input parameters may be modified as follows. Fracture toughness (both horizontal and vertical) is multiplied by the square root of the equivalence ratio. Leak-off is multiplied by the equivalence ratio. Fluid consistency index is multiplied by the equivalence ratio in the power of n+1, where n is the flow index of a power-law fluid. Proppant diameter is multiplied by the equivalence ratio. Formation permeability is multiplied by the square of the equivalence ratio. Fracture initiation points are updated to reflect the fewer number of fractures.

The updated geomodel and completion designs are then used in hydraulic fracture and/or reservoir modeling 180 so that the equivalent rock, fluid, and proppant properties are used together with the reduced number of fractures to represent the original completion design. In certain embodiments, the results of the modeling may be processed, using the same equivalence ratio values, such that the final solution of propped surface area, total surface area, fracture width, and others, are expressed in relation to the original fracture configuration.

The total original surface area is computed from the area of equivalent fractures by multiplying the latter by the equivalence ratio. The fracture width for the original fractures is computed by dividing the equivalent width by the equivalence ratio.

While the disclosure is susceptible to various modifications and alternative forms, specific embodiments thereof are shown by way of example in the drawings and description. It should be understood, however, that the drawings and detailed description thereto are not intended to limit the claims to the particular form disclosed, but on the contrary, the intention is to cover all modifications, equivalents, and alternatives falling within the scope of the claims.

What is claimed is:

1. A method for modeling hydraulic fractures comprising:
selecting a geomechanical model of a formation;
selecting a completion design for a well within the formation, wherein the completion design includes a plurality of hydraulic fractures;
selecting one or more equivalent hydraulic fractures to represent the plurality of hydraulic fractures;
determining an equivalence ratio based on the one or more equivalent hydraulic fractures;
updating the geomechanical model and the completion design using the equivalence ratio;
modeling a total surface area and fracture width of the one or more equivalent hydraulic fractures using the updated geomechanical model and the updated completion design; and
computing a total surface area and fracture width of the plurality of hydraulic fractures using the equivalence ratio and the modeled total surface area and fracture width of the one or more equivalent hydraulic fractures.

2. The method of claim 1, wherein the total surface area of the plurality of hydraulic fractures is computed by multiplying the total surface area of the one or more equivalent hydraulic fractures by the equivalence ratio.

3. The method of claim 1, wherein the fracture width of the plurality of hydraulic fractures is computed by dividing the fracture width of the one or more equivalent hydraulic fractures by the equivalence ratio.

4. The method of claim 1, wherein determining the equivalence ratio further comprises:
selecting a fracture regime based on the geomechanical model and the completion design;
determining the equivalence ratio based on the fracture regime and the one or more equivalent hydraulic fractures.

5. The method of claim 4, further comprising specifying a natural fracture complexity factor based on the formation in which the well is drilled.

6. The method of claim 4, wherein the equivalence ratio is determined by referencing a database that relates fracture regime and quantity of equivalent fractures to a corresponding equivalence ratio.

7. The method of claim 4, wherein the fracture regime is storage-viscosity, storage-toughness, leak-off-viscosity, or leak-off-toughness.

8. A method for modeling hydraulic fractures comprising:
selecting a geomechanical model of a formation;
selecting a completion design for a well within the formation, wherein the completion design includes a plurality of hydraulic fractures;
selecting a quantity of equivalent hydraulic fractures to represent the plurality of hydraulic fractures;
identifying a fracture regime based on the geomechanical model and the completion design;
determining an equivalence ratio based on the quantity of equivalent hydraulic fractures and the fracture regime;
updating the geomechanical model and the completion design using the equivalence ratio;
modeling a total surface area of the quantity of equivalent hydraulic fractures using the updated geomechanical model and the updated completion design; and
computing a total surface area of the plurality of hydraulic fractures by multiplying the total surface area of the quantity of equivalent hydraulic fractures by the equivalence ratio.

9. The method of claim 8, further comprising:
modeling a fracture width of the quantity of equivalent hydraulic fractures using the updated geomechanical model and the updated completion design; and
computing a fracture width of the plurality of hydraulic fractures by dividing the fracture width of the quantity of equivalent hydraulic fractures by the equivalence ratio.

10. The method of claim 8, wherein determining the equivalence ratio further comprises specifying a natural fracture complexity factor based on the formation in which the well is drilled.

11. The method of claim 8, wherein the equivalence ratio is determined by referencing a database of equivalence ratios that relates fracture regime and quantity of equivalent hydraulic fractures to a corresponding equivalence ratio.

12. The method of claim 11, wherein the database is populated by performing a plurality of simulations with identical numbers of fractures and differing fracture regimes and a plurality of simulations with identical fracture regimes and differing numbers of fractures.

13. The method of claim 8, wherein the fracture regime is storage-viscosity, storage-toughness, leak-off-viscosity, or leak-off-toughness.

14. The method of claim 8, wherein updating the geomechanical model comprises:
multiplying fracture toughness by the square root of the equivalence ratio;
multiplying leak-off by the equivalence ratio; and
multiplying formation permeability by the square of the equivalence ratio.

15. The method of claim 8, wherein updating the completion design comprises:
multiplying proppant diameter by the equivalence ratio; and
updating fracture initiation points to reflect the quantity of equivalent hydraulic fractures.

16. A method for modeling hydraulic fractures comprising:
selecting a completion design for a well within a formation, wherein the completion design includes a plurality of hydraulic fractures;
selecting a quantity of equivalent hydraulic fractures to represent the plurality of hydraulic fractures;
selecting an equivalence ratio based on the quantity of equivalent hydraulic fractures;
updating a geomechanical model of the formation and the completion design using the equivalence ratio;
modeling properties of the quantity of equivalent hydraulic fractures using the updated geomechanical model and the updated completion design; and
computing properties of the plurality of hydraulic fractures using the equivalence ratio and the modeled properties of the quantity of equivalent hydraulic fractures.

17. The method of claim 16, further comprising:
identifying a fracture regime based on the formation and the completion design, wherein the fracture regime is storage-viscosity, storage-toughness, leak-off-viscosity, or leak-off-toughness.

18. The method of claim 17, wherein the equivalence ratio is determined by referencing a database of equivalence ratios that relates fracture regime and quantity of equivalent hydraulic fractures to a corresponding equivalence ratio.

19. The method of claim 18, further comprising:
specifying a natural fracture complexity factor based on the formation in which the well is drilled; and
using the natural fracture complexity factor to select the equivalence ratio.

20. The method of claim 19, wherein the natural fracture complexity factor varies by depth.
